(19) United States
(12) Patent Application Publication
(10) Pub. No.: US 2026/0025913 A1
(43) Pub. Date: Jan. 22, 2026

(54) Circuit Board Structure, Manufacturing Method Thereof and Three-dimensional Electrical Connection Structure Including the Same

(71) Applicant: Dongguan Kangxiang Electronic Co., Ltd, Dongguan (CN)

(72) Inventors: MING LUO, Dongguan (CN); YUNG- CHANG LIN, Dongguan (CN); YU-HUNG LIN, Dongguan (CN); HUNG-TIEN CHANG, Dongguan (CN); HSUAN HO CHUNG, Dongguan (CN)

(21) Appl. No.: 19/238,366

(22) Filed: Jun. 14, 2025

(30) Foreign Application Priority Data
Jul. 19, 2024 (TW) 113127163

(51) Int. Cl. H05K 1/02; H05K 1/14

(52) U.S. Cl. CPC H05K 1/0277; H05K 1/147; H05K 2201/2081

(57) ABSTRACT

A circuit board structure includes a flexible core board, a first circuit layer, a first solder mask layer, a first protective layer, a rigid plate and a plurality of electrically-conductive members. The flexible core board includes a first surface and a second surface. The first circuit layer is formed on the first surface, and has a plurality of electrical connection portions. The first solder mask layer is coated on the first circuit layer and the first surface. The first solder mask layer has a plurality of opening portions aligned with the electrical connection portions. The first protective layer is disposed on the first solder resist layer and has a flat surface. The rigid plate is disposed on the second surface and corresponds to the opening portions. The electrically-conductive members are respectively formed on the electrical connection portion and exposed from the opening portion.

### BACKGROUND OF THE INVENTION

### Field of the Invention

The invention relates to a technical field of circuit board, and more particularly to a circuit board structure, a manufacturing method thereof and a three-dimensional electrical connection structure utilizing the circuit board structure, wherein the circuit board structure includes a flexible core board.

### Description of the Related Art

Circuit boards are utilized to carry electronic components, wherein traces are formed by electrically-conductive layers on the circuit boards to form electrical connections between electronic components. Electronic components transmit signals or supply power to each other through the circuit board to complete specific functions. Most of conventional circuit boards have a rigid substrate made of fiberglass and epoxy resin as a core board. Therefore, when two circuit boards or circuit boards and electronic modules are at different heights, bendable cables, wires or flexible circuit boards are necessary for electrical connection therebetween.

Therefore, various wires or flexible circuit boards must be produced besides the circuit board. This may increase the complexity of the internal configuration of the electronic device, and the large variety of electronic components also increases the cost of manufacturing and management.

### BRIEF SUMMARY OF THE INVENTION

An object of the invention is to provide a circuit board structure, a manufacturing method thereof and a three-dimensional electrical connection structure utilizing the circuit board structure, which solves the problem of complicated internal configuration of the electronic device and increased cost of manufacturing and management.

The invention provides a circuit board structure. The circuit board structure in accordance with an exemplary embodiment of the invention includes a flexible core board, a first circuit layer, a first solder mask layer, a first protective layer and a plurality of electrically-conductive members. The flexible core board includes a first surface and a second surface. The first circuit layer is formed on the first surface, wherein the first circuit layer has a plurality of electrical connection portions. The first solder mask layer is coated on the first circuit layer and the first surface, wherein the first solder mask layer has a plurality of opening portions corresponding to the electrical connection portions. The first protective layer is disposed on the first solder mask layer, wherein the first protective layer has a flat surface. The electrically-conductive members are formed on the electrical connection portions respectively and exposed from the opening portions respectively.

The invention provides a manufacturing method of a circuit board structure, including the following steps: providing a substrate comprising a flexible core board and a first electrically-conductive layer formed on a first surface of the flexible core board; forming a first circuit layer from the first electrically-conductive layer, wherein the first circuit layer has a plurality of electrical connection portions; coating a first solder mask layer on the first circuit layer and the first surface, wherein the first solder mask layer has a plurality of opening portions corresponding to the electrical connection portions; joining a first protective layer on the first solder mask layer, wherein the first protective layer has a flat surface; forming a plurality of electrically-conductive members on the electrical connection portions respectively and exposed from the opening portions respectively through a physical/chemical deposition process.

The invention provides a three-dimensional electrical connection structure, including a first circuit board, a second circuit board and a connecting circuit board. The first circuit board is disposed at a first position having a first height. The second circuit board is disposed at a second position having a second height. The connecting circuit board connects the first circuit board and the second circuit board. The first circuit board, the second circuit board and the connecting circuit board are integrally formed. The first height is different form the second height.

The circuit board structure of the present invention can realize an integrated three-dimensional electrical connection structure without cables or flexible circuit boards, thereby simplifying the internal configuration of the electronic device and significantly reducing costs of manufacturing and management.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1 to 11 are schematic views of an embodiment of a manufacturing method of a circuit board structure of the present invention;

FIG. 12 is a schematic view of an embodiment of a circuit board structure of the present invention;

FIGS. 13 to 25 are schematic views of another embodiment of a manufacturing method of a circuit board structure of the present invention;

FIGS. 26 to 36 are schematic views of yet another embodiment of a manufacturing method of a circuit board structure of the present invention;

FIG. 34 is a schematic view of an embodiment of a three-dimensional electrical connection structure of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

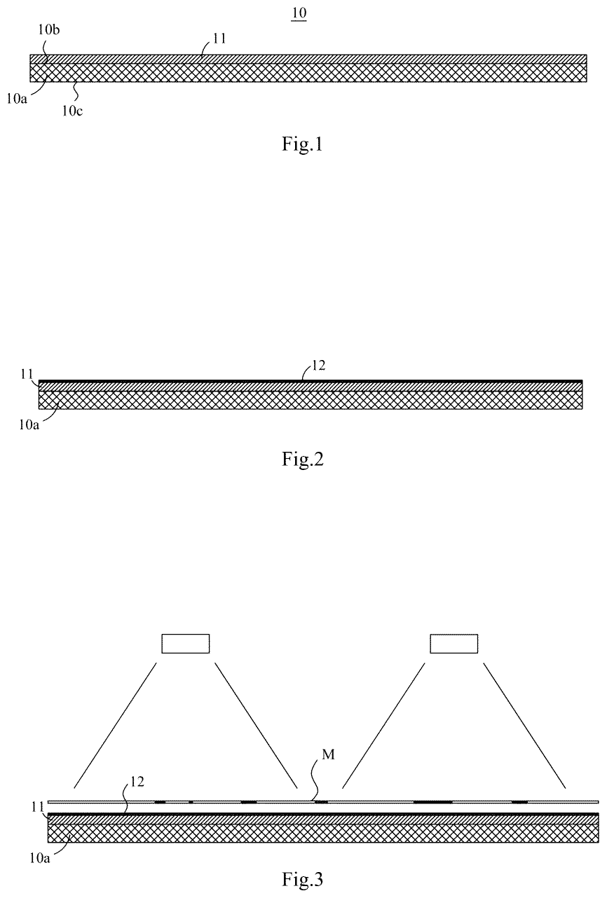

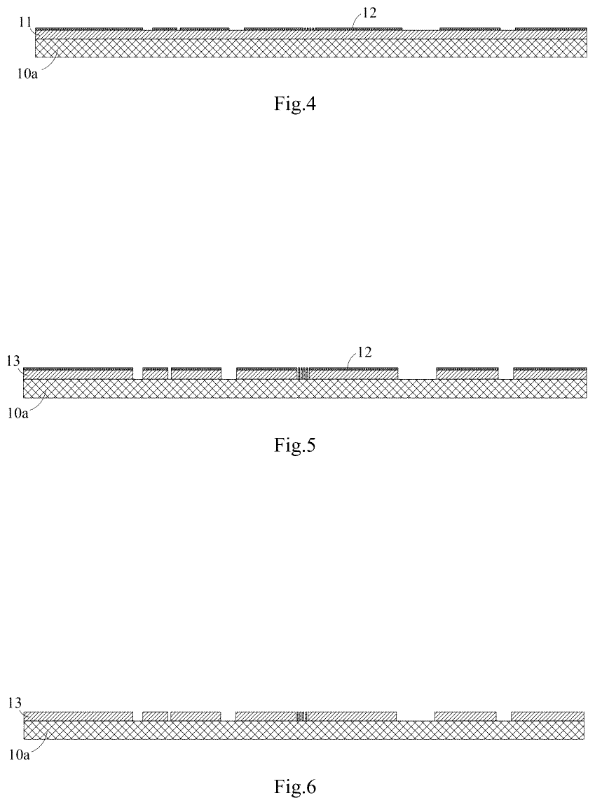

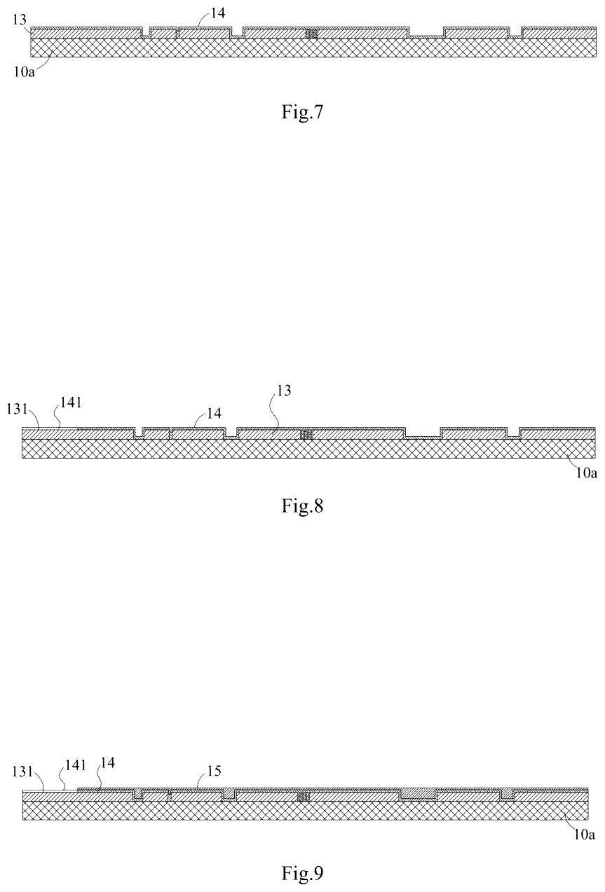

Referring to FIGS. 1 to 11, an embodiment of a manufacturing method of a circuit board is disclosed. The circuit board structure of this embodiment is a circuit board with a single electrically-conductive layer. As shown in FIG. 1, a substrate 10 is provided. The substrate 10 includes a flexible core board 10a and a first electrically-conductive layer 11 pre-pressed on the first surface 10b of the flexible core board 10a. The flexible core board 10a of this embodiment is made of flexible material, and the first electrically-conductive layer 11 is a copper foil layer. As shown in FIG. 2, a photoresist layer 12 is coated on the first electrically-conductive layer 11. As shown in FIG. 3, the photoresist layer 12 is exposed to a light (such as UV light) with a photomask M corresponding to a circuit diagram, whereby the portion of the photoresist layer 12 corresponding to the circuit is hardened. Next, as shown in FIG. 4, the unhardened photoresist layer 12 is removed, whereby the portion corresponding to the circuit diagram is covered with the cured photoresist layer 12, and a portion of the first electrically-conductive layer 11 not corresponding to the circuit diagram is exposed from the photoresist layer 12. As shown in FIG. 5, the first electrically-conductive layer 11 exposed from the photoresist layer 12 is removed through an etching process. As shown in FIG. 6, the photoresist layer 12 is totally removed to obtain a first circuit layer 13 from the first electrically-conductive layer 11. As shown in FIG. 7, a first solder mask layer 14 is coated on the first circuit layer 13 and the first surface 10b of the flexible core board 10a. Then, as shown in FIG. 8, the first solder mask layer 14 corresponding to a plurality of electrical connection portions 131 on the first circuit layer 13 is removed to form opening portions 141. The electrical connection portions 131 are a substrate structure of gold finger structures for plugging into an electrical connector or soldering pad structures for soldering pins of electronic components.

As shown in FIG. 9, a high temperature resistant plastic film is thermally pressed onto a surface of the first solder mask layer 14 to form a first protective layer 15. The surface of the first protective layer 15 is flat through the thermal press process, and the material of the first protective layer is also filled into an uneven structure of the first solder mask layer 14 caused by the height difference between the first circuit layer 13 and the first surface 10b of the flexible core board 10a, whereby a completely flat surface of the first protective layer 15 is finally formed. The region covered by the first protective layer 15 is less than the region of the first solder mask layer 14, and the first protective layer 15 has a boundary edge closed to but not exceeding the opening portions 141 of the first solder mask layer 14. That is the electrical connection portion 131 of the first circuit layer 13 is not covered by the first protective layer 15.

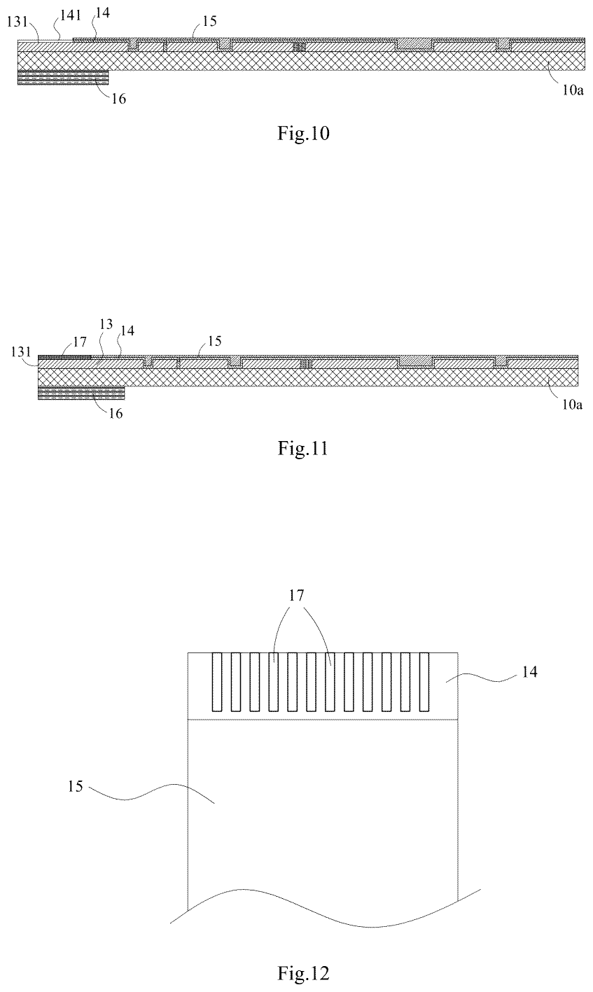

As shown in FIG. 10, a rigid plate 16 is bonded to the second surface 10c of the core material 10a, and is located at a position opposite to the electrical connection portion 131 of the first circuit layer 13. The rigid plate material 16 can strengthen the edge of the core material 10a and serve as a plug-in structure for electrical connector, such as a board-to-board electrical connector.

Finally, as shown in FIG. 11, a plurality of electrically-conductive members 17 are deposited on the electrical connection portion 131 of the first circuit layer 13 through a physical/chemical deposition process. The electrically-conductive member 17 is exposed from the opening portions 141 of the first solder mask layer 14 for the electrical connections with electronic components. The electrically-conductive member 17 in this embodiment is made of gold (Au). The electrical connection portion 131 of this embodiment is formed on the edge of the flexible core board 10a and cooperates with the electrically-conductive member 17 to form a golden finger structure for plugging.

Referring to FIG. 12, an embodiment of the circuit board structure of the present invention is disclosed. The circuit board structure is sized to desired dimensions. The electrically-conductive members 17 are located at the edge of the circuit board structure. The first solder mask layer 14 surrounds the electrically-conductive members 17. The boundary edge of the first protective layer 15 is close to the electrically-conductive member 17 but not exceeding the position of the electrically-conductive member 17.

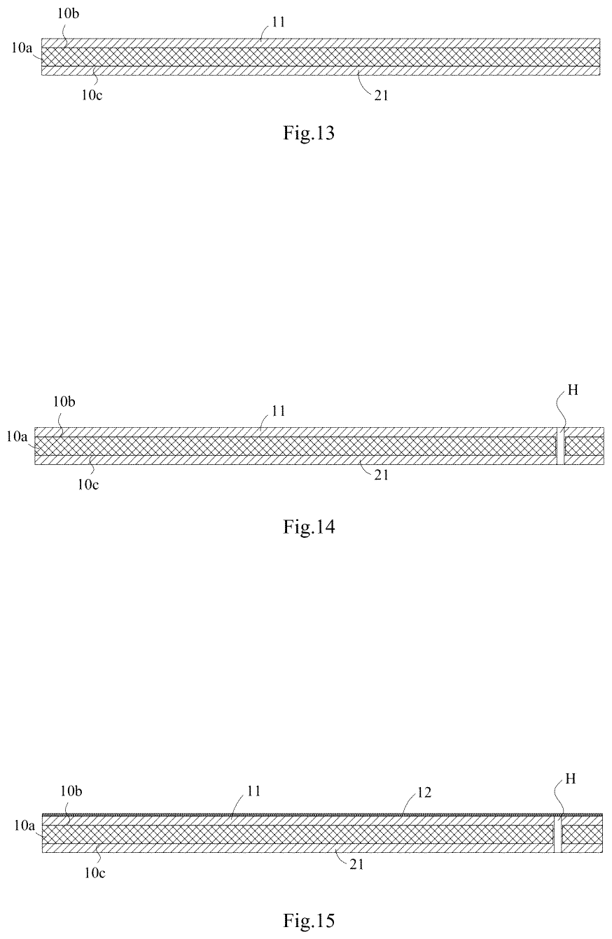

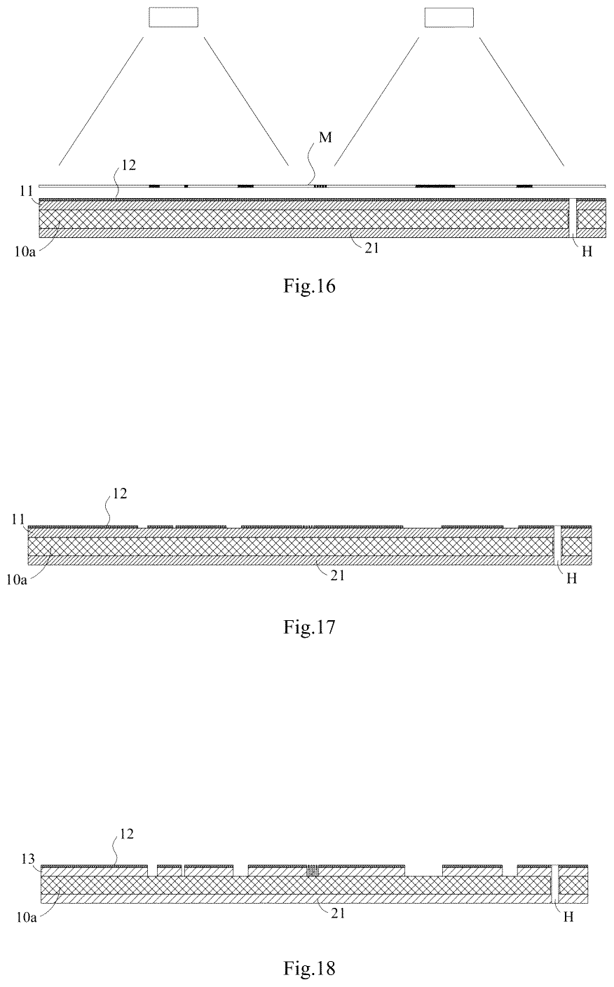

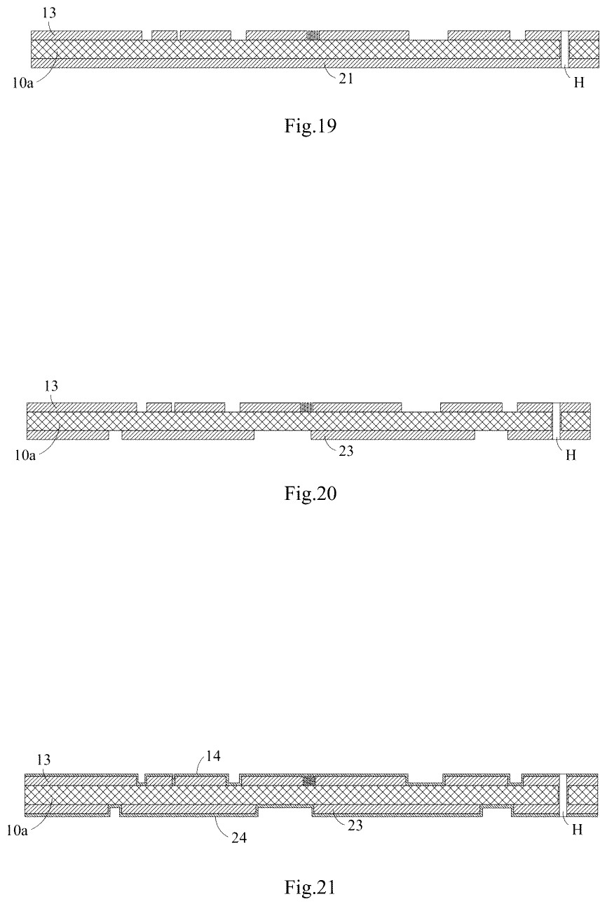

Referring to FIGS. 13 to 24, another embodiment of the manufacturing method of the circuit board structure of the present invention is disclosed. The circuit board structure of this embodiment is a circuit board with two electrically-conductive layers. As shown in FIG. 13, a circuit board substrate 10 is provided. The circuit board substrate 10 includes a flexible core board 10a, a first electrically-conductive layer 11 pre-pressed on a first surface 10b of the flexible core board 10a, and a second electrically-conductive layer 21 pre-pressed on a second surface 10c of the flexible core board 10a. The flexible core board 10a in this embodiment is made of flexible material. The first electrically-conductive layer 11 and the second electrically-conductive layer 21 are copper foil layers. As shown in FIG. 14, a through hole H is formed through a drilling process, and then a conductor is plated on the wall of the through hole H through an electroplating process, whereby the first electrically-conductive layer 11 and the second electrically-conductive layer 21 are electrically connected. Next, as shown in FIG. 15, a photoresist layer 12 is coated on the first electrically-conductive layer 11. Next, as shown in FIG. 16, the photoresist layer 12 is exposed to a light (such as UV light) with a photomask M corresponding to a circuit diagram, whereby a portion of the photoresist layer 12 corresponding to the circuit diagram is hardened. Next, as shown in FIG. 17, the unhardened photoresist layer 12 is removed, whereby the portion corresponding to the circuit diagram is covered with the cured photoresist layer 12, and the portion of the first electrically-conductive layer 11 not corresponding to the circuit diagram is exposed from the photoresist layer 12. As shown in FIG. 18, the first electrically-conductive layer 11 exposed from the photoresist layer 12 is removed through an etching process. As shown in FIG. 19, the photoresist layer 12 is totally removed to obtain the first circuit layer 13.

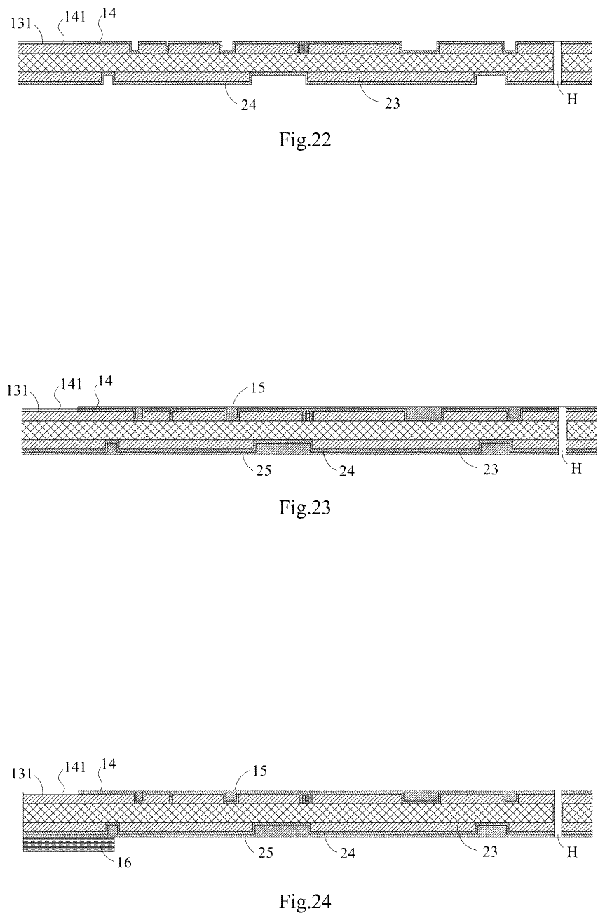

As shown in FIG. 20, the second circuit layer 23 is formed from the second electrically-conductive layer 21 using the same process as the first circuit layer 13. Next, as shown in FIG. 21, a first solder mask layer 14 is coated on the first circuit layer 13, and a second solder mask layer 24 is coated on the second circuit layer 23. Then, as shown in FIG. 22, the first solder mask layer 14 corresponding to the electrical connection portions 131 on the first circuit layer 13 is removed to form a plurality of opening portions 141. The electrical connection portions 131 are base structure of gold finger structures for plugging into an electrical connector or soldering pad structures for soldering electronic component pins.

Next, as shown in FIG. 23, a high temperature resistant plastic film is thermally pressed onto a surface of the first solder mask layer 14 to form the first protective layer 15. The surface of the first protective layer 15 is flat, and the material of the first protective layer 15 is filled into the uneven structure of the first solder mask layer 14 caused by the height difference between the first circuit layer 13 and the first surface 10b of the flexible core board 10a, whereby the first protective layer 15 finally forms a completely flat surface, and the region covered by the first protective layer 15 is less than the first solder mask layer 14. The first protective layer 15 has a boundary edge closed to but not exceeding the opening portions 141 where the electrical connection portion 131 of the circuit layer 13 is located. Similarly, a high-temperature resistant plastic film is thermally pressed onto a surface of the second solder mask layer 24 to form the second protective layer 25.

Next, as shown in FIG. 24, a rigid plate 16 is bonded to the second protective layer 25 and located at a position corresponding to the electrical connection portion 131 of the first circuit layer 13. The rigid plate material 16 can strengthen the edge of the core material 10a and serve as a plug-in structure.

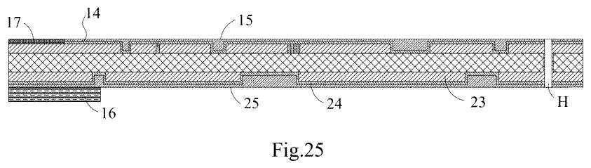

Finally, as shown in FIG. 25, electrically-conductive members 17 are deposited on the electrical connection portion 131 of the first circuit layer 13 through a physical/chemical deposition process. The electrically-conductive members 17 are exposed from the opening portions 141 of the first solder mask layer 14 for electrical connections with electronic components. The electrically-conductive members 17 in this embodiment is made of gold (Au). The electrical connection portions 131 of this embodiment is formed on the edge of the flexible core board 10a and cooperates with the electrically-conductive members 17 to form a golden finger structure for plugging.

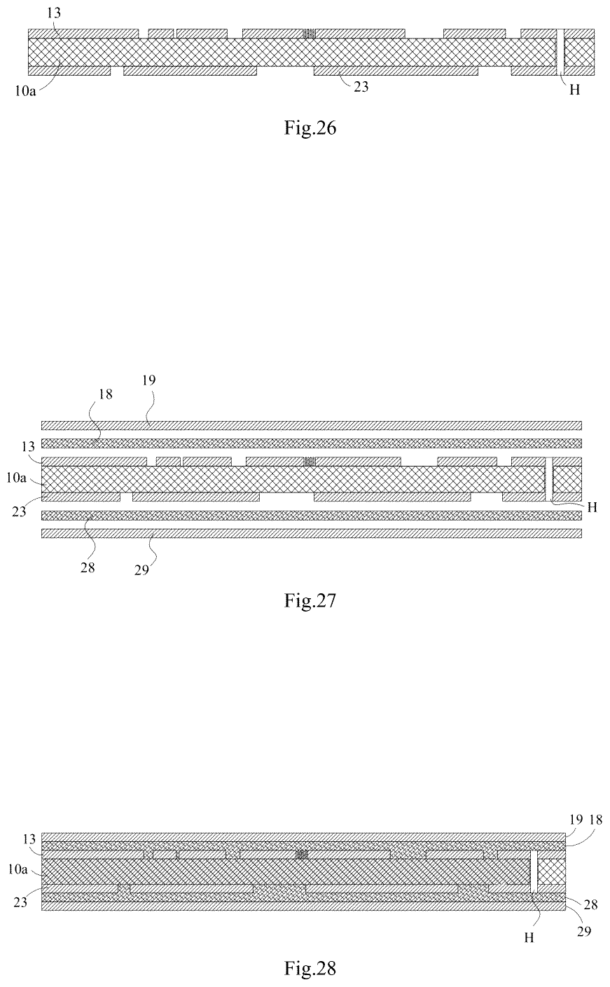

Referring to FIGS. 26 to 35, yet another embodiment of the manufacturing method of the circuit board structure of the present invention is disclosed. As shown in FIG. 26, a circuit board structure as shown in FIG. 20 is provided. The circuit board structure has a flexible core board 10a, a first circuit layer 13 formed on the first surface 10b of the flexible core board 10a, and a second circuit layer 23 formed on a second surface 10c of the flexible core board 10a. Next, as shown in FIGS. 27 and 28, a first insulation layer 18 and a third electrically-conductive layer 19 are pressed on the first circuit layer 13. A second insulation layer 28 and a fourth electrically-conductive 29 are similarly pressed on the second circuit layer 23. The first insulation layer 18 and the second insulation layer 28 are polypropylene (PP) plates, and the third electrically-conductive layer 19 and the fourth electrically-conductive layer 29 are copper foil layers.

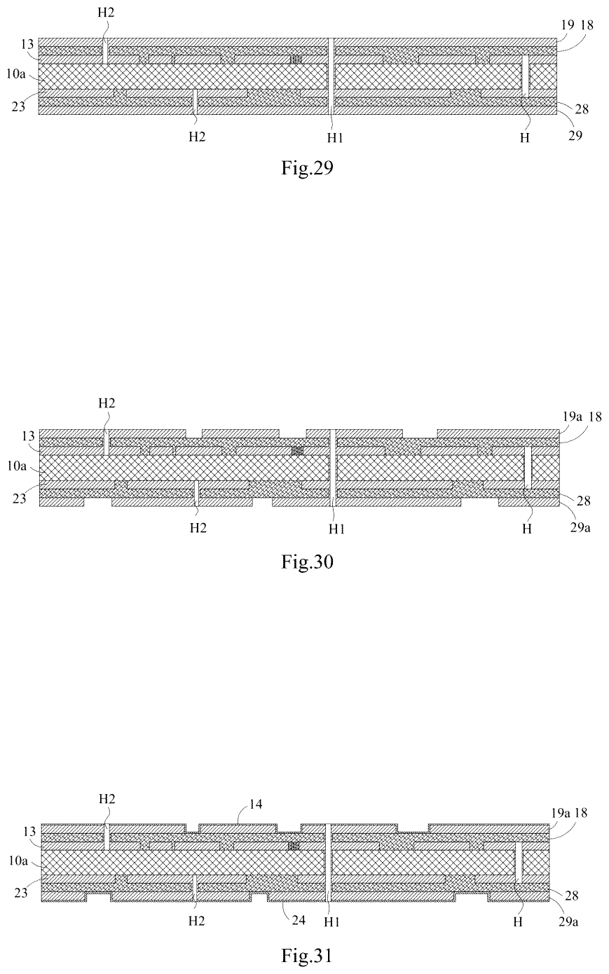

Then as shown in FIG. 29, through holes H1 and blind holes H2 are formed on the circuit board structure by a drilling process, and the through holes H that previously penetrated the flexible core board 10a, the first circuit layer 13 and the second circuit layer 23 becomes a buried via hole. Then, an electroplating process is used to form conductors on the walls of the through holes H1 and blind holes H2 for electrical connection of the first circuit layer 13 and the third electrically-conductive layer 19, of the second circuit layer 23 and the fourth electrically-conductive layer 29, or/and of the third electrically-conductive layer 19, the first circuit layer 13, the second circuit layer 23 and the fourth electrically-conductive layer 29.

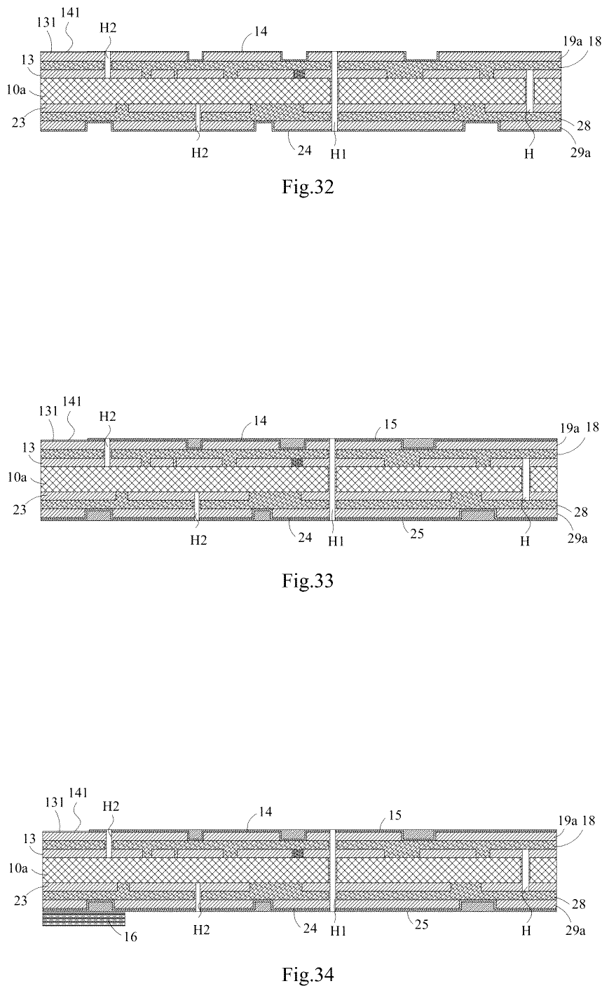

As shown in FIG. 30, a third circuit layer 19a is formed from the third electrically-conductive layer 19, and a fourth circuit layer 29a is similarly formed from the fourth electrically-conductive layer 29. Then, as shown in FIG. 31, the first solder mask layer 14 is coated on the third circuit layer 19a, and the second solder mask layer 24 is coated on the fourth circuit layer 29a. Next, as shown in FIG. 32, a portion of the first solder mask layer 14 corresponding to the electrical connection portion 191 on the third circuit layer 19a is removed to form opening portions 141. The electrical connection portions 191 are a base structure of golden finger structures for plugging into an electrical connector or soldering pad structures for soldering pins of electronic components.

Then as shown in FIG. 33, a high temperature resistant plastic film is thermally pressed onto a surface of the first solder mask layer 14 to form a first protective layer 15. The surface of the first protective layer 15 is flat, and the material of the first protective layer 15 is filled into an uneven structure of the first solder mask layer 14 caused by the height difference between the third circuit layer 19a and the first insulation layer 18, whereby the first protective layer 15 eventually forms a completely flat surface. The region of the first protective layer 15 does not exceed the portion of the first solder mask layer 14 where the electrical connection portion 191 of the third circuit layer 19a is located. Similarly, a high-temperature resistant plastic film is thermally pressed onto the surface of the second solder mask layer 24 to form the second protective layer 25.

As shown in FIG. 34, a rigid plate 16 is bonded to the second protective layer 25 and located at a position corresponding to the electrical connection portion 131 of the first circuit layer 13. The rigid plate material 16 can strengthen the edge of the flexible core board 10a and serve as a plug-in structure.

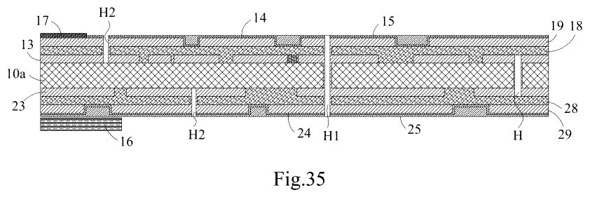

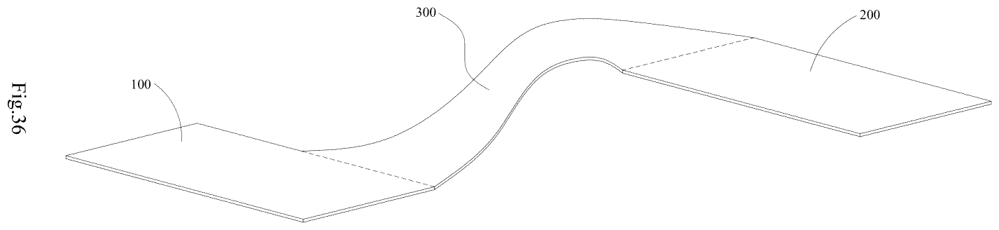

Finally, as shown in FIG. 35, the electrically-conductive members 17 is deposited on the electrical connection portions 191 of the third circuit layer 19a through a physical/chemical deposition process. The electrically-conductive members 17 are exposed from the opening portions 141 of the first solder mask layer 14 for electrical connections with electronic components. The electrically-conductive members 17 in this embodiment is made of gold (Au). The electrical connection portion 191 of this embodiment is formed on the edge of the flexible core board 10a and cooperates with the conductor 17 to form a golden finger structure for plugging.

Referring to FIG. 36, an embodiment of the three-dimensional electrical connection structure of the present invention is disclosed. The three-dimensional electrical connection structure of this embodiment includes a first circuit board 100, a second circuit board 200 and a connecting circuit board 300. The first circuit board 100 is disposed at a first position having a first height. The second circuit board 200 is disposed at a second position having a second height. The first height and the second height are relative to a reference plane, such as the bottom of the electronic device housing. The first height may be the same as or different from the second height. The connecting circuit board 300 connects the first circuit board 100 and the second circuit board 200. The first circuit board 100, the second circuit board 200 and the connecting circuit board 300 have an integrated structure, and the first circuit board 100, the second circuit board 200 and the connecting circuit board 300 are all constituted by the above-mentioned circuit board structure. That is, in the above-mentioned manufacturing method, after the circuit board structure is completed, it can be cut into the desired shape and size according to the designed arrangement. The first circuit board 100 and the second circuit board 200 can be used to carry electronic components, and the connecting circuit board 300 has traces connecting the first circuit board 100 and the second circuit board 200.

The circuit board structure of the present invention can realize an integrated three-dimensional electrical connection structure without cables or flexible circuit boards, thereby simplifying the internal configuration of the electronic device and significantly reducing costs of manufacturing and management.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit board structure, comprising:
a flexible core board including a first surface and a second surface;
a first circuit layer formed on the first surface, wherein the first circuit layer has a plurality of electrical connection portions;
a first solder mask layer coated on the first circuit layer and the first surface, wherein the first solder mask layer has a plurality of opening portions corresponding to the electrical connection portions;
a first protective layer disposed on the first solder mask layer, wherein the first protective layer has a flat surface; and
a plurality of electrically-conductive members formed on the electrical connection portions respectively and exposed from the opening portions respectively.

2. The circuit board structure as claimed in claim 1, further comprising a rigid plate disposed on the second surface.

3. The circuit board structure as claimed in claim 1, wherein the first circuit layer is formed by copper, and the electrically-conductive members are formed by gold.

4. The circuit board structure as claimed in claim 1, wherein the first protective layer is a plastic film.

5. The circuit board structure as claimed in claim 1, wherein the first protective layer has a boundary edge in vicinity of the opening portions, whereby a portion of the first solder mask layer corresponding to the opening portions is exposed.

6. The circuit board structure as claimed in claim 1, further comprising:
a second circuit layer formed on the second surface;
a second solder mask layer coated on the second circuit layer and the second surface; and
a second protective layer formed on the second solder mask layer, wherein the second protective layer has a flat surface.

7. The circuit board structure as claimed in claim 4, further comprising a rigid plate disposed on the second s protective layer.

8. A circuit board structure, comprising:
a flexible core board including a first surface and a second surface;
a first circuit layer formed on the first surface, wherein the first circuit layer has a plurality of electrical connection portions;
a second circuit layer formed on the second surface;
a first insulation layer formed on the first circuit layer and the first surface;
a third circuit layer formed on the first insulation layer, wherein the third circuit layer has a plurality of electrical connection portions;
a second insulation layer formed on the second circuit layer and the second surface;
a fourth circuit layer formed on the second insulation layer;
a first solder mask layer coated on the third circuit layer and the first insulation layer, wherein the first solder mask layer has a plurality of opening portions corresponding to the electrical connection portions
a first protective layer disposed on the first solder mask layer, wherein the first protective layer has a flat surface;
a second solder mask layer coated on the fourth circuit layer and the second insulation layer;
a second protective layer disposed on the second solder mask layer, wherein the second protective layer has a flat surface;
a rigid plate disposed on the second protective layer; and
a plurality of electrically-conductive members formed on the electrical connection portions respectively and exposed from the opening portions respectively.

9. A three-dimensional electrical connection structure, comprising:
a first circuit board disposed at a first position having a first height;
a second circuit board disposed at a second position having a second height; and
a connecting circuit board connecting the first circuit board and the second circuit board;
wherein the first circuit board, the second circuit board and the connecting circuit board are integrally formed;
wherein the first height is different form the second height.

10. The three-dimensional electrical connection structure as claimed in claim 9, wherein the first circuit board, the second circuit board and the connecting circuit board have a circuit board structure as claimed in claim 1.

11. The three-dimensional electrical connection structure as claimed in claim 9, wherein the first circuit board, the second circuit board and the connecting circuit board have a circuit board structure as claimed in claim 6.

12. The three-dimensional electrical connection structure as claimed in claim 9, wherein the first circuit board, the second circuit board and the connecting circuit board have a circuit board structure as claimed in claim 8.
